(19) United States
(12) Patent Application Publication
(10) Pub. No.: US 2006/0073663 A1
(43) Pub. Date: Apr. 6, 2006

(54) Method of manufacturing semiconductor device

(76) Inventor: Toshihiko Iinuma, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/237,919

(22) Filed: Sep. 29, 2005

(30) Foreign Application Priority Data
Sep. 29, 2004 (JP) 2004-283455
Apr. 4, 2005 (JP) 2005-107229

(51) Int. Cl. H01L 21/336

(52) U.S. Cl. 438/300

(57) ABSTRACT

A method of manufacturing a semiconductor device includes forming a semiconductor region containing silicon and an insulator region on a major surface of a semiconductor substrate containing silicon as a main component; depositing a semiconductor film containing silicon as a main component on the semiconductor region and the insulator region; depositing a metal film which forms a silicide film by reacting with silicon on the semiconductor film; annealing the semiconductor substrate to form a first silicide film on the semiconductor region by reacting the metal film with silicon in the semiconductor film and in the semiconductor substrate under the semiconductor film in the semiconductor region and to form a second silicide film on the insulator region by reacting the metal film with the silicon in the semiconductor film in the insulator region; and selectively removing the second silicide film on the basis of a difference between the component of silicon and metal in the first silicide film and the component of silicon and metal in the second silicide film.

### CROSS-REFERENCE TO RELATED APPLICATIONS

This application is based upon and claims the benefit of priority from the prior Japanese Patent Applications No. 2004-283455, filed on Sep. 29, 2004 and No. 2005-107229, filed on Apr. 4, 2005, the entire contents of which are incorporated herein by reference.

### BACKGROUND OF THE INVENTION

1. Field of the Invention

The present invention relates to a method of manufacturing a semiconductor device.

2. Background Art

In recent years, micropatterning of a semiconductor device advances. Accordingly, junction depths of an extension layer and a contact layer in source and drain regions of a transistor must be decreased. However, the extension layer and the contact layer are merely reduced in thickness, parasitic resistances of the source and drain layers disadvantageously increase. In order to suppress the resistances from being increased, a method of forming a silicide layer on the source and drain regions is frequently used. The silicide film is formed by reaction between a metal and silicon. Therefore, when a metal film is directly deposited on the source and drain regions, silicon in the source and drain regions are corroded by silicidation. For this reason, a depth from the bottom of the silicide layer to the junction portion of the source and drain layers decreases. Furthermore, an extension layer and a contact layer are shallowly formed, a silicide film or metal atoms diffused from the silicide film may reach the junction portion of the source or drain diffusion layer. When the silicide film reaches the junction portion of the contact layer, junction leakage occurs in the source and drain regions.

A technique (elevated source-drain technique) that electively epitaxially grows a silicon film in the source and drain regions to suppress the metal film from reacting with the silicon in the source and drain regions is known. However, it is difficult to selectively epitaxially grow silicon in a uniform thickness in the source and drain regions. In particular, at an end portion of the source and drain regions, the thickness of the silicon film selectively epitaxially grown tends to decrease. Silicon is corroded by silicidation at the end portion of the source and drain regions as at the other portion, so that a depth from the bottom of the silicide layer to the junction portion of the source and drain layers decreases at the end portion. Therefore, the silicide layer or the metal atoms diffused from the silicide film may still reach the junction portion of the source or drain diffusion layer at the end portion. Furthermore, a silicon selective epitaxial growing technique itself used in the elevated source-drain technique is a technique having a high degree of difficulty. Use of this technique complicates the steps in manufacturing a semiconductor device (see U.S. Pat. No. 6,770,942).

Therefore, there is provided a method of manufacturing a semiconductor device which suppresses a silicide film formed on source and drain layers of a transistor from penetrating a junction portion of the source and drain layers.

### SUMMARY OF THE INVENTION

A method of manufacturing a semiconductor device according to an embodiment of the present invention includes forming a semiconductor region containing silicon and an insulator region on a major surface of a semiconductor substrate containing silicon as a main component; depositing a semiconductor film containing silicon as a main component on the semiconductor region and the insulator region; depositing a metal film which forms a silicide film by reacting with silicon on the semiconductor film; annealing the semiconductor substrate to form a first silicide film on the semiconductor region by reacting the metal film with silicon in the semiconductor film and in the semiconductor substrate under the semiconductor film in the semiconductor region, and to form a second silicide film on the insulator region by reacting the metal film with the silicon in the semiconductor film in the insulator region; and

selectively removing the second silicide film on the basis of a difference between the composition of silicon and metal in the first silicide film and the composition of silicon and metal in the second silicide film.

A method of manufacturing a semiconductor device according to an embodiment of the present invention includes forming a semiconductor region containing silicon and an insulator region on a major surface of a semiconductor substrate containing silicon as a main component; depositing a semiconductor film containing silicon as a main component on the semiconductor region and the insulator region; depositing a first metal film which forms a silicide film by reacting with silicon on the semiconductor film; forming a cap film on the first metal film, the cap film being made of a second metal or a compound containing the second metal which has a melting point higher than that of the first metal film; annealing the semiconductor substrate at a temperature lower than the melting point of the second metal or a compound containing the second metal to form a first silicide film on the semiconductor region by reacting the first metal film with silicon in the semiconductor film and in the semiconductor substrate under the semiconductor film in the semiconductor region and to form a second silicide film on the insulator region by reacting the first metal film with the silicon in the semiconductor film in the insulator region; and selectively removing the second silicide film on the basis of a difference between the component of silicon and metal in the first silicide film and the component of silicon and metal in the second silicide film.

### BRIEF DESCRIPTION OF THE DRAWINGS

FIG. 1 is a sectional view showing a method of manufacturing a MISFET according to an embodiment of the present invention;

FIG. 2 is a sectional view showing a method of manufacturing a MISFET following FIG. 1;

FIG. 3 is a sectional view showing a method of manufacturing a MISFET following FIG. 2;

FIG. 4 is a sectional view showing a method of anufacturing a MISFET following FIG. 3;

FIG. 5 is a sectional view showing a method of anufacturing a MISFET following FIG. 4;

FIG. 6 is a sectional view showing a method of manufacturing a MISFET following FIG. 5;

FIG. 7 is a graph related a ratio of thicknesses TM/TSi of the nickel film 100 and the amorphous silicon film 90 and a ratio of resistances ρsb/ρsa of the second silicide film 120 before and after selective etching;

FIG. 8 shows a manner of agglomerating a nickel film in the prior art;

FIG. 9 is a sectional view showing a method of manufacturing a semiconductor device according to the second embodiment of the present invention; and

FIG. 10 is a sectional view showing a method of manufacturing a semiconductor device following FIG. 9.

### DETAILED DESCRIPTION OF THE INVENTION

Embodiments of the present invention will be described below with reference to the accompanying drawings. The embodiments do not limit the present invention.

### (FIRST EMBODIMENT)

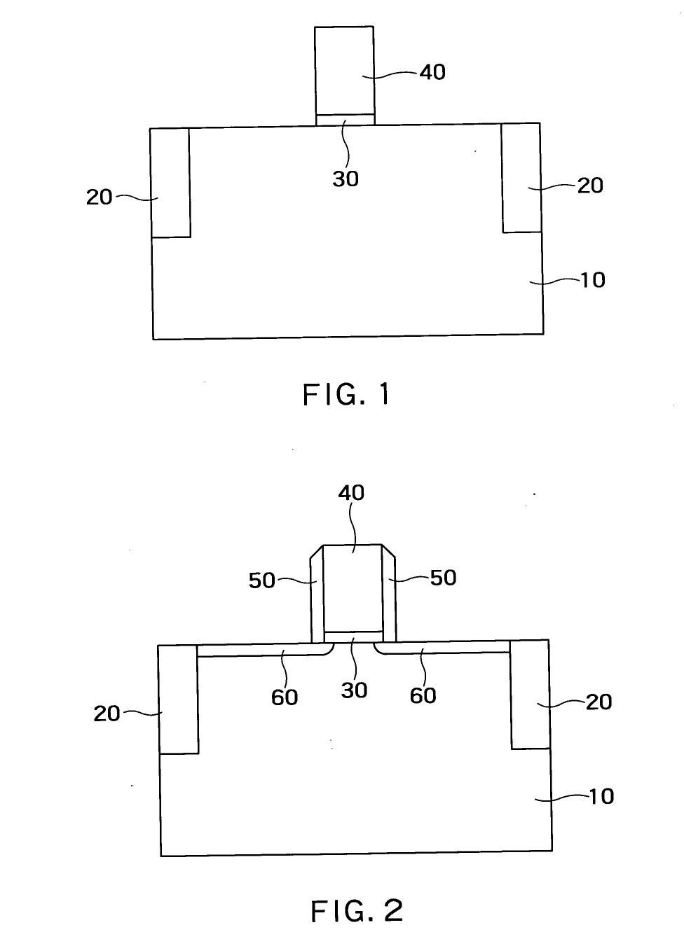

FIGS. 1 to 6 are cross-sections showing a flow of a method of manufacturing a MISFET (metal Insulator Semiconductor Field Effect Transistor) according to a first embodiment of the present invention. As shown in FIG. 1, a p-type silicon substrate 10 is prepared as a semiconductor substrate. An element isolation portion 20 (for example, STI (Shallow Trench Isolation)) constituted by a silicon oxide film is formed on a major surface of the p-type silicon substrate 10.

An insulating film and polysilicon are sequentially formed, and the insulating film and a polysilicon laminated structure film are patterned to form a gate insulating film 30 and a gate electrode 40.

As shown in FIG. 2, a silicon nitride film having a thickness of 2 to 10 nm is deposited and subjected to anisotropic etching such as RIE (Reactive Ion Etching). In this manner, an offset spacer 50 constituted by a silicon nitride film is formed on a sidewall of the gate electrode 40. An n-type impurity such as arsenic is ion-implanted by using the gate electrode 40 and the offset spacer 50 as masks. In this manner, an extension layer 60 of an n-type source-drain diffusion layer is formed on the major surface of the p-type silicon substrate 10 in a self-aligning manner.

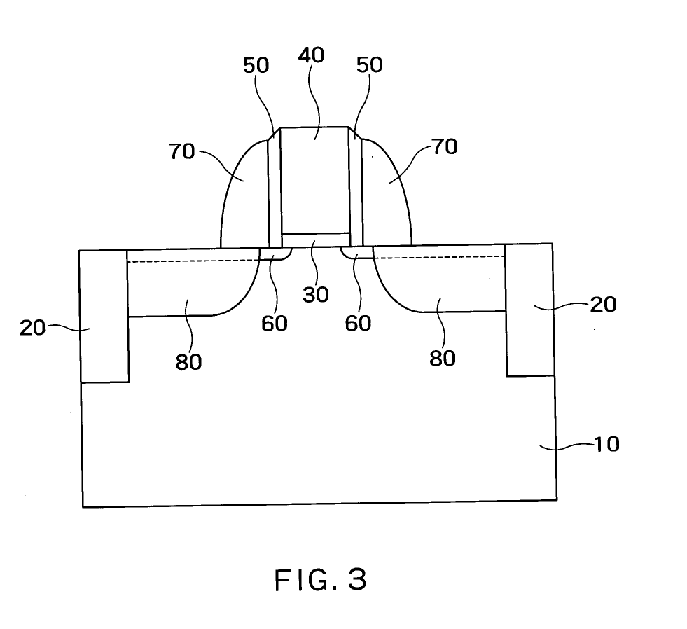

As shown in FIG. 3, a silicon nitride film is deposited again and subjected to anisotropic etching such as RIE. In this manner, a gate sidewall film 70 constituted by a silicon nitride film is formed. An n-type impurity such as arsenic or phosphorous is ion-implanted by using the gate electrode 40, the offset spacer 50, and the gate sidewall film 70 as masks, and high-temperature, short-time thermal treatment such as RTA (Rapid Thermal Anneal) is performed. In this manner, a contact region 80 of an n+-type source and drain diffusion layers is formed on the major surface of the p-type silicon substrate 10 in a self-aligning manner. At this time, the n-type impurity is also doped in the gate electrode 40 consisting of polysilicon, and the gate electrode 40 consisting of n-type doped polysilicon is obtained.

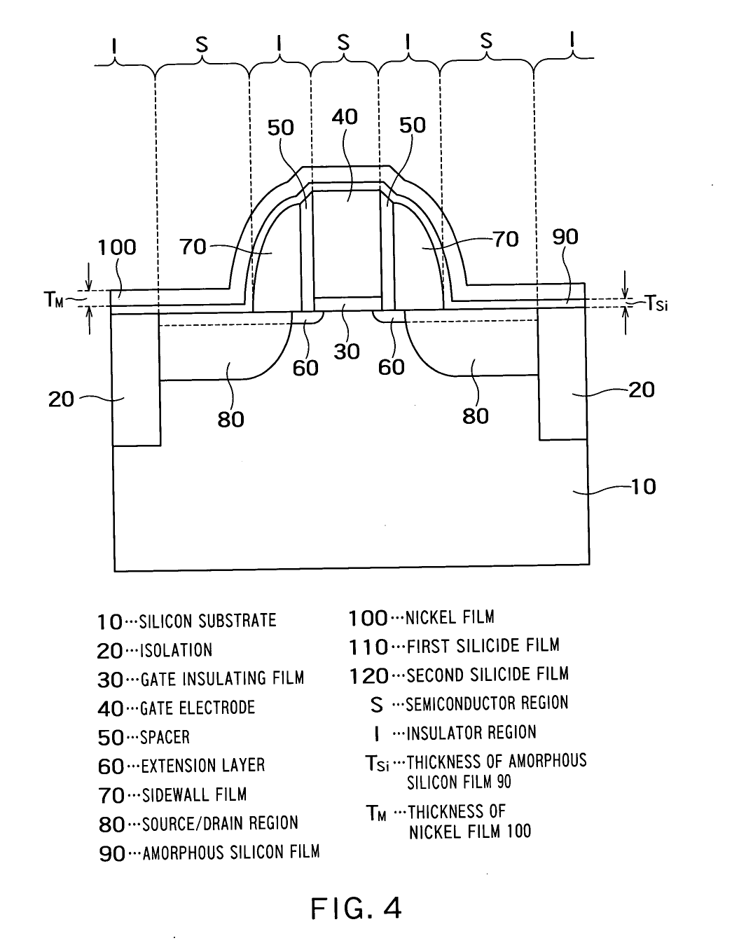

As shown in FIG. 4, an amorphous silicon film 90 having a thickness TSi is deposited on an entire major surface of the p-type silicon substrate 10. In this case, the amorphous silicon film 90 is formed on not only the surface of a semiconductor region S including the source-drain region 80 and the gate electrode 40 but also the surface of an insulator region I including the isolation 20, the offset spacer 50, and the gate sidewall film 70. As a metal film which forms a silicide film by reacting with silicon, a nickel film 100 is deposited on the amorphous silicon film 90. The thickness of the nickel film 100 is represented by TM. Typically, the thickness TSi of the amorphous silicon film 90 is 6 nm, and the thickness TM of the nickel film 100 is 10 nm.

First RTA is performed at a temperature of 400° C. or less, e.g., 350° C. In this manner, in the semiconductor region S, the nickel film 100 reacts with only the amorphous silicon film 90, but also the source-drain region 80 under the amorphous silicon film 90 and silicon on the surface of the gate electrode 40. As a result, nickel silicide (NixSi) is formed as a first silicide film 110. On the other hand, in the insulator region I, the nickel film 100 reacts with the amorphous silicon film 90. As a result, nickel silicide (NiySi) is formed as a second silicide film 120.

At this time, in the semiconductor region S, the nickel film 100 can sufficiently receive silicon supplied from the amorphous silicon film 90 and the source-drain region 80 or the amorphous silicon film 90 and the gate electrode 40. Therefore, the first silicide film 110 becomes nickel silicide having a composition of NixSi (1≦x≦2). On the other hand, in the insulator region I, the nickel film 100 is present on the element isolation portion 20 and the gate sidewall film 70 which are constituted by a silicon oxide film or a silicon nitride film. Therefore, the nickel film 100 receives silicon supplied from only the amorphous silicon film 90. As a result, a small amount of silicon contributes to silicidation. For this reason, the second silicide film 120 becomes nickel-rich silicide having a composition of NiySi (y>2).

The first RTA is performed at a temperature of 400° C. or higher, the nickel film 100 near a boundary between the semiconductor region S and the insulator region I flows into the source-drain layer 80. In this manner, the first silicide film 110 is formed to have a large thickness at only the end portion of the source-drain layer 80. Therefore, the first RTA is preferably performed at a temperature of 400° C. or less.

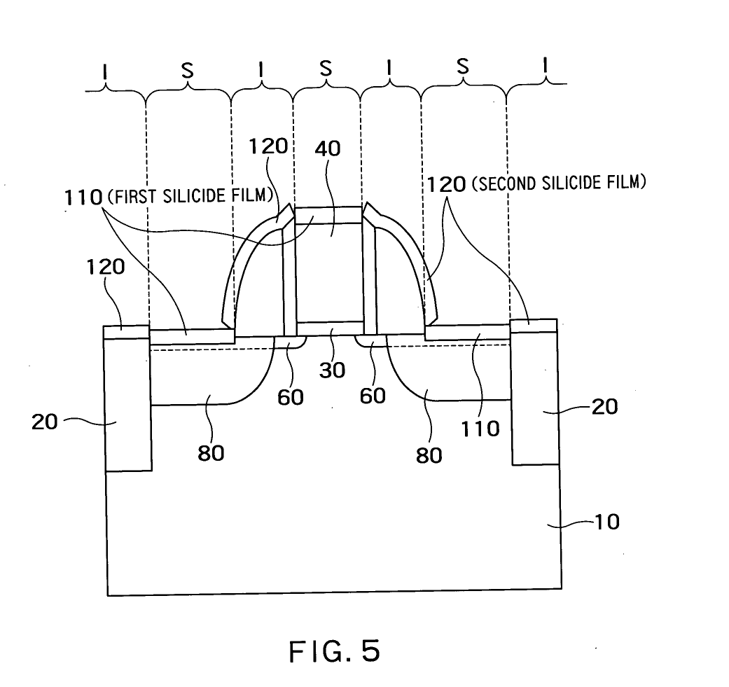

The second silicide film 120 (NiySi (y>2)) having a high nickel content can be removed with a sulfuric acid-hydrogen peroxide solution, an ammonia-hydrogen peroxide solution, or a solution mixture of dilute hydrochloric acid and hydrogen peroxide solution which are used in a normal silicide process. On the other hand, the first silicide film 110 (NixSi (1≦x≦2)) having a relatively low nickel content cannot be easily etched with a sulfuric acid-hydrogen peroxide solution, an ammonia-hydrogen peroxide solution, or a solution mixture of dilute hydrochloric acid and hydrogen peroxide solution. More specifically, when the sulfuric acid-hydrogen peroxide solution, the ammonia-hydrogen peroxide solution, or the solution mixture of dilute hydrochloric acid and hydrogen peroxide solution is used, the element isolation portion 20 is etched at a rate which is higher than an etching rate of the first silicide film 110 and has a high selectivity. In this manner, as shown in FIG. 5, the second silicide film 120 is selectively removed, so that the first silicide film 110 can be left.

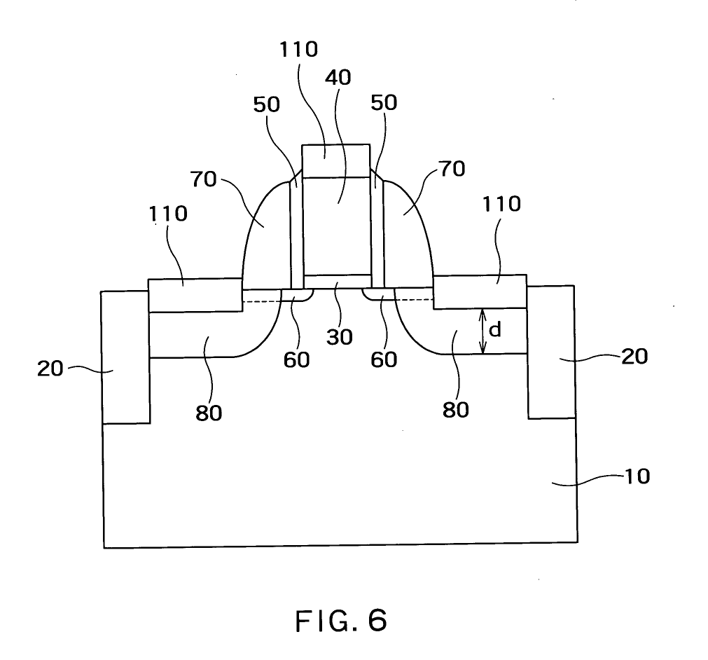

Second RTA is performed at a temperature of 500° C. to 530° C. In this manner, as shown in FIG. 6, the first silicide film 110 further reacts with silicon, the composition of NixSi (1≧x≧2) changes into nickel mono-silicide (NiSi) having a low resistance. For this reason, the sheet resistance of the first silicide film 110 can be decreased.

Thereafter, a wiring layer connected to the first silicide film 110 on the source-drain region and the gate electrode 40 is formed. Furthermore, a passivation film or the like is deposited to complete a semiconductor device.

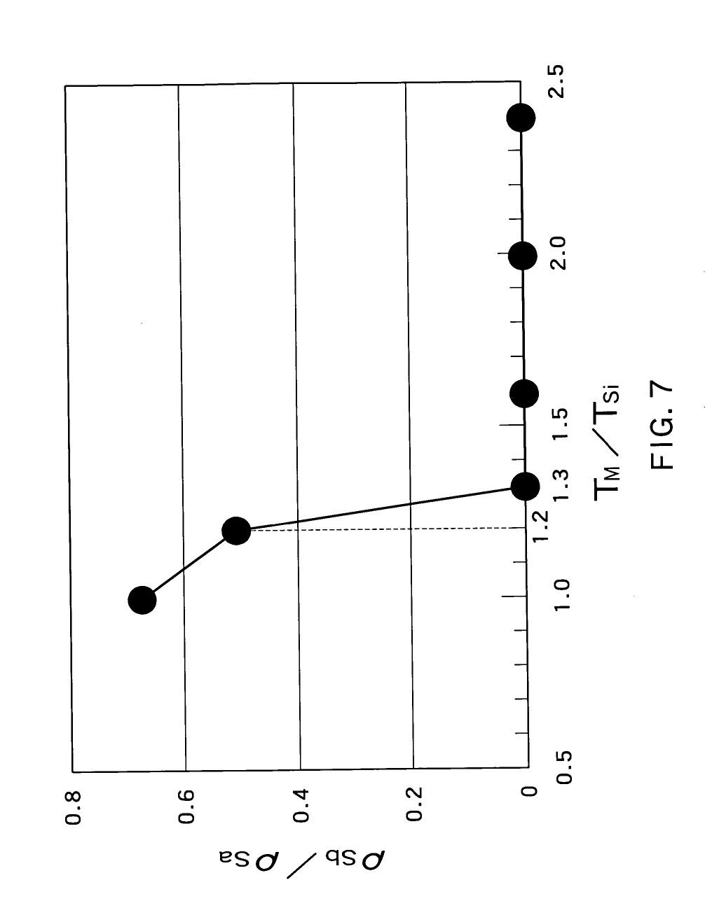

Referring to FIG. 7, the thickness TSi of the amorphous silicon film 90 and the thickness TM of the nickel film 100 will be considered below. FIG. 7 is a graph related a ratio of thicknesses TM/TSi of the nickel film 100 and the amorphous silicon film 90 and a ratio of resistances ρsb/ρsa of the second silicide film 120 before and after selective etching. Reference symbol ρsb denotes a sheet resistance of the second silicide before the selective etching process, and reference symbol ρsa denotes a sheet resistance of the second silicide after the selective etching process.

The graph in FIG. 7 was obtained by the following experiment. An insulating film, an amorphous silicon film, and a nickel film were sequentially stacked on a silicon substrate. An RTA process at about 350° C. was performed to cause amorphous silicon to react with nickel. The sheet resistance (ρsb) of the silicide film formed on the insulating film was measured. Thereafter, the second silicide film was selectively etched. After this etching, the sheet resistance (ρsa) of the second silicide film was measured again. As a result, the graph shown in FIG. 7 was obtained.

When the second silicide is entirely removed after the selective etching process, the sheet resistance ρsa becomes infinite. For this reason, the ratio of resistances ρsb/ρsa becomes 0. On the other hand, the second silicide is left after the selective etching process, the ratio of resistances ρsb/ρsa becomes high. Furthermore, when any second silicide is not etched, the ratio of resistances ρsb/pas is equal to 1.0.

When the ratio of thicknesses TM/TSi is 1.0 or less, the ratio of resistances ρsb/ρsa is about 0.7. It is understood that the second silicide is left. When the ratio of thicknesses TM/TSi is 1.2, the ratio of resistances ρsb/ρsa becomes 0.5. It is understood that half of the second silicide is removed. Furthermore, when the ratio of thicknesses TM/TSi is 1.3 or more, the ratio of resistances ρsb/ρsa becomes 0. It is understood that the second silicide is entirely removed. For this reason, the ratio of thicknesses TM/TSi must be at least 1.2 or more, more preferably, the ratio of thicknesses TM/TSi is 1.3 or more.

In general, in order to make the composition of the second silicide layer NiySi (y=1), depending on the conditions of the first RTA, the ratio of thicknesses TM/TSi must be about 0.5 or less. When the ratio of thicknesses TM/TSi is about 1.3, the composition of the second silicide layer is NiySi (k>2). On the other hand, since the first silicide film 110 can receive silicon supplied from the source-drain region 80 or the gate electrode 40, under the conditions of the first RTA, independently of the ratio of thicknesses TM/TSi, the composition is NixSi (1≦x≦2).

In this embodiment, on the basis of the difference of the compositions of silicon and metal in the first silicide film 110 and the second silicide film 120, the second silicide film 120 is selectively removed.

Limitation of the thickness TM and the thickness TSi will be described below. Under the condition in which the ratio of thicknesses TM/TSi is 1.2 or more, when the thickness TM is excessive, most of silicon of the source-drain region 80 is corroded by silicidation. In this manner, a distance d (see FIG. 6) between the bottom of the first silicide film 110 and the junction surface of the source-drain region 80 becomes short, and the first silicide film 110 may penetrate the junction portion of the source-drain region 80. Under the same conditions, when the thickness TSi is excessive, silicon is sufficiently supplied to the nickel film 100 in the insulator region I. Therefore, the composition of the second silicide film 120 is equal to the composition of the nickel film 100 (NixSi (1≦x≦2)). As a result, the second silicide film 120 cannot be selectively etched. For these reasons, when it is assumed that the depth of a nickel silicide (NiSI) film eating into the source-drain diffusion layer is 30 nm or less, the thickness TSi and the thickness TM are preferably 20 nm or less and 30 nm or less, respectively. A tolerance of the depth of the nickel silicide film eating into the source-drain diffusion layer is dependent on the depth of the source-drain diffusion layer. In recent years in which micropatterning of devices advances, the depth of the nickel silicide film eating into the source-drain diffusion layer is preferably suppressed to 30 nm or less.

For example, it is assumed that a thickness (TNi) of a nickel film to be deposited is 1.3 times a thickness (TSi) of an amorphous silicon film. In this case, when the thickness of a nickel mono-silicide (NiSi) film finally formed is represented by TNiSi, Formula 1 is generally established.
TNiSi=1.8×TNi=1.8×1.3×TSi (Formula 1)

Where the depth of the nickel silicide film eating into the source-drain diffusion layer is represented by DNiSi, Formula 2 is established.
DNiSi=TNiSi−TSi=(1.8×1.3−1)×TSi (Formula 2)

When the depth DNiSi is made 30 nm or less, the thickness TSi of the silicon film is about 22 nm or less, the thickness TNi of the nickel film is about 30 nm or less.

The method of manufacturing a semiconductor device according to the embodiment can manufacture a semiconductor device having the same structure as that of a semiconductor device formed by an elevated source-drain technique without using a selective epitaxial growing technique. More specifically, as shown in FIG. 4, the amorphous silicon film 90 is deposited on the source-drain region 80 to increase the distance “d” between the bottom of the first silicide film 110 and a p-n junction surface of the source-drain diffusion layer. In this manner, junction leakage in the source-drain region 80 can be suppressed.

The embodiment can be realized by the step of depositing the amorphous silicon film 90 without the selective epitaxial growing technique. Since the step of depositing the amorphous silicon film 90 can be executed more easily than the selective epitaxial growing technique, reductions in cycle time and in cost can be achieved.

In general, an amorphous silicon film can be formed at a temperature lower than a film forming temperature of a polysilicon film. For example, since the film forming temperature of polysilicon is 600° C. or higher, the film forming temperature of amorphous silicon is 500 to 550° C. When the film forming temperature is high, a profile of the diffusion layer of the source-drain region changes, and the activation rate of an impurity in the diffusion layer decreases.

Therefore, when the amorphous silicon film 90 is formed before the nickel film 100 is formed, the profile of the diffusion layer of the source-drain region 80 is not changed, and the activation rate of the impurity in the diffusion layer does not decrease.

The amorphous silicon film 90 does not have crystal grain boundary unlike a polysilicon film. For this reason, the amorphous silicon film 90 uniformly reacts with a nickel film in comparison with the polysilicon film. As a result, the thickness uniformity of a nickel silicide film formed by using the amorphous silicon film 90 is more preferable than that of a nickel silicide film formed by using polysilicon.

In the embodiment, although nickel silicide is used in the silicide film, in place of the nickel silicide, a silicide material such as cobalt silicide (CoSi2), palladium silicide, or platinum silicide may be used. In this modification, the same effect as that obtained in the embodiment by adjusting the ratio of thicknesses TM/TSi and by adjusting selective etching conditions depending on a silicide material can be obtained.

When the nickel film 100 is formed in the insulator region I without the amorphous silicon film 90, nickel is agglutinated on the insulator region I in the step of silicidation, and nickel may flow into the source-drain region 80. This causes junction leakage at the end portion of the source-drain region 80. According to the embodiment, not only on the semiconductor region S, but also on the insulator region I, the amorphous silicon film 90 is formed. Therefore, since the nickel film 100 on the insulator region I reacts with the amorphous silicon film 90, nickel does not flow into the source-drain region 80. For this reason, junction leakage at the end portion of the source-drain region 80 can be suppressed.

In the embodiment, as the semiconductor film (90) and the gate electrode 40, a silicon compound in which germanium or the like is mixed may be used in place of amorphous silicon and polysilicon.

Although the embodiment shows a method of manufacturing an n-type MOSFET, the present invention can be applied to a p-type MOSFET. Furthermore, an n-type MOSFET and a p-type MOSFET can also be simultaneously formed on the same substrate by using a photograph technique.

### (SECOND EMBODIMENT)

A method of manufacturing a semiconductor device according to a second embodiment of the present invention.

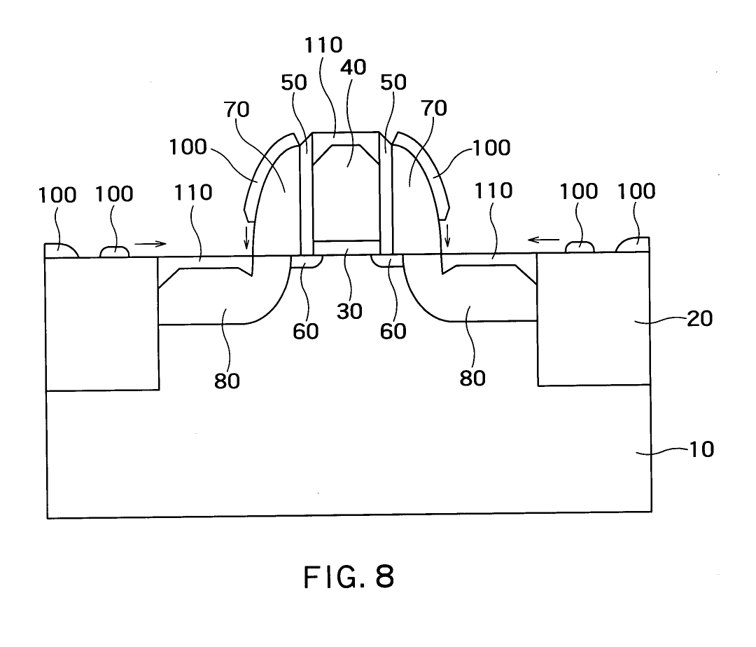

FIG. 8 shows a manner of agglomerating a nickel film in the prior art. A metal film (nickel film) formed on an insulating film in an insulator region I is agglomerated by RTA. The agglomerated metal flows into an end portion of the source-drain region 80. This decreases a distance d (see FIG. 6) at the end portion of the source-drain region 80 to cause junction leakage.

In the first embodiment, an amorphous silicon film 90 is formed between the insulator region I and a nickel film 100 to make it possible to suppress metal from flowing into the source-drain region 80.

However, in the first embodiment, the following fact is understood. That is, amorphous silicon is deposited on the insulating film (silicon oxide film) in the insulator region I to have a thickness of about 6 nm, and a nickel film is deposited to have a thickness of about 10 nm. Thereafter, when an RTA process is performed at 350° C., a nickel silicide (NiySi (Si (y>2)) film is agglutinated on a silicon oxide film.

In the RTA step, in order to completely suppress a metal from flowing into the end portion of the source-drain region 80, an agglutinating phenomenon of the nickel silicide (NiySi (y>2)) film must be suppressed.

Therefore, in the second embodiment, a cap film 101 consisting of a metal having a melting point higher than that of nickel is formed on the nickel film 100. In this manner, the nickel silicide film can be prevented from being agglutinated, and the metal can be effectively suppressed from flowing into the source-drain region 80.

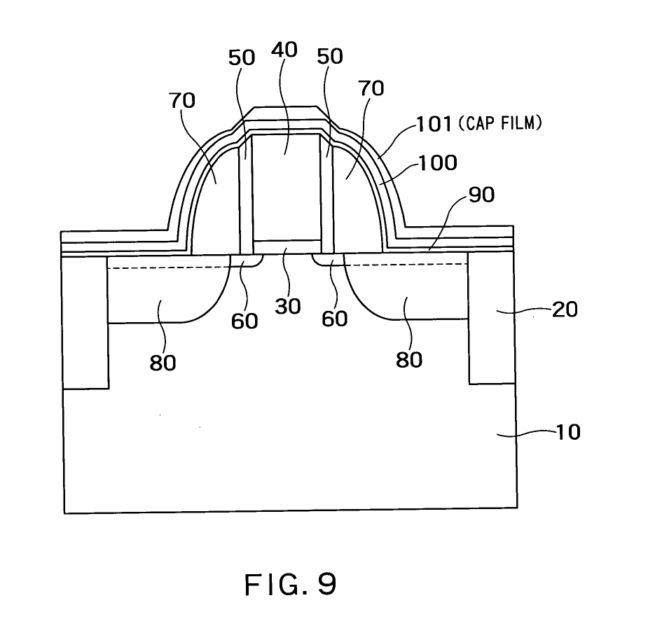

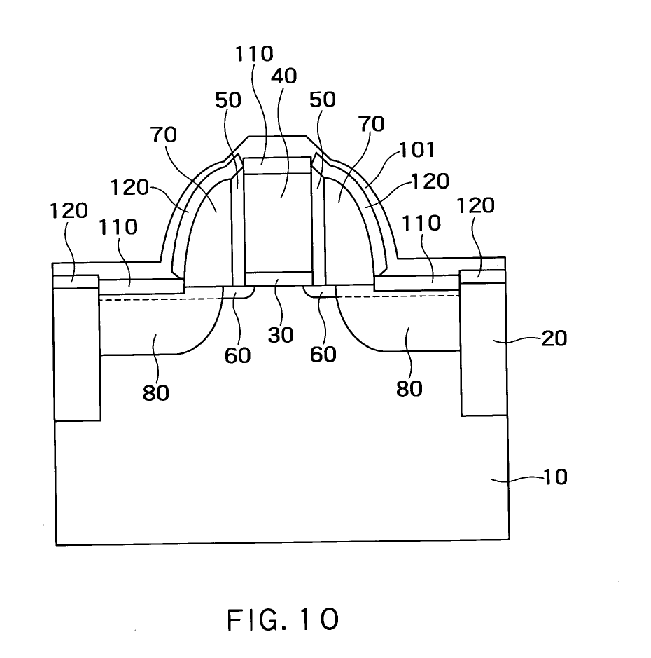

FIGS. 9 and 10 are sectional views showing a flow of a method of manufacturing a semiconductor device according to the second embodiment of the present invention. As described above with reference to FIGS. 1 to 3, the gate electrode 40, the source-drain region 80, and the like are formed on the silicon substrate 10.

As shown in FIG. 9, the amorphous silicon film 90 (for example, about 6 nm) and the nickel film 100 (for example, about 10 nm) serving as a first metal film are deposited on an entire surface of a silicon substrate 10. The process performed here is the same as the process performed in the first embodiment.

Subsequently, the cap film 101 is deposited on the nickel film 100 to have a thickness of 10 nm to 100 nm (for example, 30 nm). The cap film 101 consists of a second metal having a melting point higher than that of the nickel film 100 serving as the first metal film. For example, the second metal is any one of tungsten, molybdenum, titanium, zirconium, tantalum, hafnium, vanadium, and niobium. The cap film 101 may consist of a compound of the second metal. For example, the compound of the second metal is any one of tungsten nitride, molybdenum nitride, titanium nitride, zirconium nitride, tantalum nitride, hafnium nitride, vanadium nitride, and niobium nitride.

For example, first RTA is performed at 350° C. The temperature of the first RTA is equal to or higher than the melting point of the nickel film 100 and lower than the melting point of the cap film 101. In this manner, as in the first embodiment, in a semiconductor region S, the nickel film 100 reacts with not only the amorphous silicon film 90 but also silicon on the source-drain region 80 under the amorphous silicon film 90 and the gate electrode 40. As a result, nickel silicide (NixSi (1<x<2) is formed as the first silicide film 110. On the other hand, in the insulator region I, the nickel film 100 reacts with the amorphous silicon film 90. As a result, nickel silicide (NiySi (y>2)) is formed as a second silicide film 120.

In this RTA step, since the cap film 101 does not react with silicon or nickel, the cap film 101 remains without changing in state. In this manner, the cap film 101 compresses the second silicide film 120 (NiySi (y>2)) film 120 formed on an element isolation portion 20 with physical force. As a result, the second silicide (NiySi (y>2)) film 120 is not agglutinated in the RTA step, and do not flow into the end portion of the source-drain region 80.

The cap film 101 and the second silicide (NiySi (y>2)) film 120 having a high nickel content can be removed with a sulfuric acid-hydrogen peroxide solution, an ammonia-hydrogen peroxide solution, or a solution mixture of dilute hydrochloric acid and hydrogen peroxide solution. Therefore, the cap film 101 and the nickel silicide (NiySi (y>2)) film 120 are selectively etched to make it possible to leave the nickel silicide (NixSi (1≦x≦2)) film 110.

Thereafter, the processes subsequent to the second RTA process are the same as those in the first embodiment. In this manner, a semiconductor device as shown in FIG. 6 is completed.

According to the second embodiment, the cap film 101 compresses the nickel silicide (NiySi (y>2)) film 120 formed on the element isolation portion 20 with physical force. As a result, since the nickel silicide (NiySi (y>2)) film 120 flows into the end portion of the source-drain region 80, junction leakage at the end portion of the source-drain region 80 can be suppressed.

1. A method of manufacturing a semiconductor device comprising:
forming a semiconductor region containing silicon and an insulator region on a major surface of a semiconductor substrate containing silicon as a main component;
depositing a semiconductor film containing silicon as a main component on the semiconductor region and the insulator region;
depositing a metal film which forms a silicide film by reacting with silicon on the semiconductor film;
annealing the semiconductor substrate to form a first silicide film on the semiconductor region by reacting the metal film with silicon in the semiconductor film and in the semiconductor substrate under the semiconductor film in the semiconductor region, and to form a second silicide film on the insulator region by reacting the metal film with the silicon in the semiconductor film in the insulator region; and
selectively removing the second silicide film on the basis of a difference between the composition of silicon and metal in the first silicide film and the composition of silicon and metal in the second silicide film.

2. The method of manufacturing a semiconductor device according to claim 1, wherein the thickness of the semiconductor film is equal to or less than 20 nm.

3. The method of manufacturing a semiconductor device according to claim 1, wherein
the semiconductor film is an amorphous silicon film, a polysilicon film, or a mixed film of silicon and germanium.

4. The method of manufacturing a semiconductor device according to claim 1, wherein
the metal film is made of nickel.

5. The method of manufacturing a semiconductor device according to claim 1, wherein
the thickness of the metal film is 1.2 times or more the thickness of the semiconductor film.

6. The method of manufacturing a semiconductor device according to claim 4, wherein
the second silicide film is removed by using a mixture solution of a hydrogen peroxide solution with a sulfuric acid, an ammonia, or a diluted hydrochloric acid.

7. The method of manufacturing a semiconductor device according to claim 4, wherein
the annealing temperature for forming the first silicide and the second silicide is 400° C. or less.

8. The method of manufacturing a semiconductor device according to claim 4 further comprising, after removing the second silicide film,
annealing the semiconductor substrate at a temperature higher than the annealing temperature for forming the first silicide and the second silicide.

9. The method of manufacturing a semiconductor device according to claim 4, wherein
the first silicide film is made of NixSi (1<x<2) , and the second silicide film is made of NiySi (y>2).

10. A method of manufacturing a semiconductor device comprising:
forming a semiconductor region containing silicon and an insulator region on a major surface of a semiconductor substrate containing silicon as a main component;
depositing a semiconductor film containing silicon as a main component on the semiconductor region and the insulator region;
depositing a first metal film which forms a silicide film by reacting with silicon on the semiconductor film;
forming a cap film on the first metal film, the cap film being made of a second metal or a compound containing the second metal which has a melting point higher than that of the first metal film;
annealing the semiconductor substrate at a temperature lower than the melting point of the second metal or a compound containing the second metal to form a first silicide film on the semiconductor region by reacting the first metal film with silicon in the semiconductor film and in the semiconductor substrate under the semiconductor film in the semiconductor region and to form a second silicide film on the insulator region by reacting the first metal film with the silicon in the semiconductor film in the insulator region; and
selectively removing the second silicide film on the basis of a difference between the component of silicon and metal in the first silicide film and the component of silicon and metal in the second silicide film.

11. The method of manufacturing a semiconductor device according to claim 10, wherein
the second metal is any one of tungsten, molybdenum, titanium, zirconium, tantalum, hafnium, vanadium, and niobium, and the compound containing the second metal is any one of tungsten nitride, molybdenum nitride, titanium nitride, zirconium nitride, tantalum nitride, hafnium nitride, vanadium nitride, and niobium nitride.

12. The method of manufacturing a semiconductor device according to claim 10, wherein
the thickness of the semiconductor film is equal to or less than 20 nm.

13. The method of manufacturing a semiconductor device according to claim 10, wherein
the semiconductor film is an amorphous silicon film, a polysilicon film, or a mixed film of silicon and germanium.

14. The method of manufacturing a semiconductor device according to claim 10, wherein
the first metal film is made of nickel.

15. The method of manufacturing a semiconductor device according to claim 10, wherein
the thickness of the first metal film is 1.2 times or more the thickness of the semiconductor film.

16. The method of manufacturing a semiconductor device according to claim 14, wherein
the second silicide film is removed by using a mixture solution of a hydrogen peroxide solution with a sulfuric acid, an ammonia, or a diluted hydrochloric acid.

17. The method of manufacturing a semiconductor device according to claim 14, wherein
the annealing temperature for forming the first silicide and the second silicide is 400° C. or less.

18. The method of manufacturing a semiconductor device according to claim 14 further comprising, after removing the second silicide film,
annealing the semiconductor substrate at a temperature higher than the annealing temperature for forming the first silicide and the second silicide.

19. The method of manufacturing a semiconductor device according to claim 14, wherein
the first silicide film is made of NixSi (1≦x≦2) , and the second silicide film is made of NiySi (y>2).
